(19) United States
(12) Patent Application Publication
(10) Pub. No.: US 2024/0128154 A1
(43) Pub. Date: Apr. 18, 2024

(54) THERMALLY CONDUCTIVE FILM-LIKE ADHESIVE, SEMICONDUCTOR PACKAGE, AND METHOD OF PRODUCING SAME

(71) Applicant: FURUKAWA ELECTRIC CO., LTD., Tokyo (JP)

(72) Inventor: Minoru MORITA, Tokyo (JP)

(73) Assignee: FURUKAWA ELECTRIC CO., LTD., Tokyo (JP)

(21) Appl. No.: 18/531,002

(22) Filed: Dec. 6, 2023

Related U.S. Application Data
(63) Continuation of application No. PCT/JP2022/015182, filed on Mar. 28, 2022.

(30) Foreign Application Priority Data
Jul. 13, 2021 (JP) 2021-116012

(51) Int. Cl. H01L 23/373; H01L 23/00; H01L 23/498; H01L 25/065

(52) U.S. Cl. CPC H01L 23/3735; H01L 23/3731; H01L 23/49822; H01L 24/05; H01L 24/45; H01L 25/0657; H01L 2224/05005; H01L 2224/05022; H01L 2224/45005; H01L 2224/4502; H01L 2225/06506; H01L 2225/0651; H01L 2924/04894; H01L 2924/0665; H01L 2924/351

(57) ABSTRACT

Provided is a thermally conductive film-like adhesive capable of sufficiently advancing a curing reaction under milder conditions, capable of effectively suppressing residual voids between the adhesive and a wiring board in a semiconductor package to be obtained when used as a die attach film, and capable of obtaining a semiconductor package excellent in heat releasing property inside the package. In addition, provided are a semiconductor package using the thermally conductive film-like adhesive and a method of producing the same.

### CROSS-REFERENCE TO RELATED APPLICATIONS

This application is a Continuation of PCT International Application No. PCT/JP2022/015182 filed on Mar. 28, 2022, which claims priority under 35 U.S.C. § 119 (a) to Japanese Patent Application No. 2021-116012 filed in Japan on Jul. 13, 2021. Each of the above applications is hereby expressly incorporated by reference, in its entirety, into the present application.

### TECHNICAL FIELD

The present invention relates to a thermally conductive film-like adhesive, a semiconductor package, and a method of producing the same.

### BACKGROUND ART

A stacked MCP (Multi Chip Package) in which semiconductor chips are multistacked has recently been widely spread, and is mounted as a memory package for a mobile phone or a portable audio device. In addition, along with multi-functionality of a mobile phone and the like, high densification and high integration of a semiconductor package have also been advanced. Along with such advance, multistacking of semiconductor chips has been advanced.

A film-like adhesive (a die attach film or a die bonding film) is used for bonding a wiring board and a semiconductor chip or bonding semiconductor chips in a process of producing such a memory package. Along with multistacking of the chips, there is an increasing demand for a thinner die attach film. In addition, recently, heat is likely to be generated on a surface of a semiconductor element due to miniaturization of a wafer wiring rule, and it is required to release the heat to the outside of a semiconductor package. Therefore, the film-like adhesive is also required to have high thermal conductivity.

In order to design a film-like adhesive having a small thickness and high thermal conductivity, the film-like adhesive is highly filled with an inorganic filler (thermally conductive filler) having a small particle diameter. However, when the film-like adhesive is highly filled with the thermally conductive filler having a small particle diameter, fluidity of the film-like adhesive decreases. Due to this decrease in fluidity, voids are likely to be generated at an interface in mounting a semiconductor chip on a wiring board. When voids are present at an interface, not only adhesion between the semiconductor chip and the wiring board decreases, but also dissipation of heat inside a semiconductor package via the substrate is hindered.

Patent Literature 1 describes that a varnish is prepared by mixing a high molecular weight acrylic rubber, a phenol resin, an epoxy resin, an alumina filler, tetraphenylphosphonium tetraphenylborate as a curing catalyst, and a silane coupling agent in respective specific amounts in a solvent, and an adhesive sheet having high thermal conductivity is obtained using the varnish. According to the technique described in Patent Literature 1, by disposing a silicon chip on a lead frame via the adhesive sheet, an interface thermal resistance between the adhesive layer and the lead frame can be reduced to 0.15 K/W or less, and a total of the interface thermal resistance and an internal thermal resistance of the adhesive layer (total thermal resistance) can also be reduced to 0.55 K/W or less.

In addition, Patent Literature 2 describes a film-like adhesive containing an epoxy resin (A), an epoxy resin curing agent (B), a polymer component (C) containing a phenoxy resin, and an inorganic filler (D) having an average particle diameter and a particle diameter at a cumulative distribution frequency of 90% within specific ranges in respective specific amounts, and having a surface arithmetic average roughness Ra of 3.0 μm or less and a thickness of 1 μm or more and less than 10 μm. According to the technique described in Patent Literature 2, in the film-like adhesive, generation of voids after a die attach step is suppressed, an adhesive force with an adherend is increased, and thermal conductivity is excellent.

### CITATION LIST

### Patent Literatures

Patent Literature 1: JP-A-2016-219720 (“JP-A” means an unexamined published Japanese patent application)
Patent Literature 2: Japanese Patent No. 6858315

### SUMMARY OF INVENTION

### Technical Problem

When a film-like adhesive is used as a die attach film, usually, one surface of the film-like adhesive is attached to a semiconductor wafer, the other surface is brought into close contact with a dicing film, the semiconductor wafer is divided (diced) using the dicing film as a base to prepare semiconductor chips, and the semiconductor chips are peeled (picked up) from the dicing film together with the film-like adhesive using a pickup collet on a die bonder. Then, the semiconductor chips are thermocompression-bonded (die-attached) onto a wiring board to cure the film-like adhesive, whereby the semiconductor chips are mounted on the wiring board via the film-like adhesive. In order to sufficiently cure the film-like adhesive, the mounting substrate is exposed to a high temperature of about 180° C. for about one hour after the thermocompression bonding. Recently, a pressure oven has been used for the high temperature heating after the thermocompression bonding. By using the pressure oven, there is an advantage that voids generated between the film-like adhesive and the wiring board during thermocompression bonding can be discharged over time simultaneously with a curing reaction.

Meanwhile, in consideration of damage to a semiconductor package and energy efficiency, the film-like adhesive is desirably cured in a lower temperature range. The present inventors have studied conventional film-like adhesives including the technique described in Patent Literature 1 from this viewpoint. As a result, it has been found that when a heating temperature by a pressure oven is lowered to about 120° C., a curing catalyst does not sufficiently act to make a curing reaction insufficient, and when a curing catalyst (for example, an imidazole compound) that acts even in a lower temperature range is used, the curing reaction itself proceeds, but voids between the film-like adhesive and the wiring board cannot be sufficiently discharged, and voids tend to remain at an interface.

The present invention has been made in view of the above circumstances, and an object of the present invention is to provide a thermally conductive film-like adhesive capable of sufficiently advancing a curing reaction under milder conditions, capable of effectively suppressing residual voids between the adhesive and a wiring board in a semiconductor package to be obtained when used as a die attach film, and capable of obtaining a semiconductor package excellent in heat releasing property inside the package. Another object of the present invention is to provide a semiconductor package using the thermally conductive film-like adhesive and a method of producing the same.

As a result of intensive studies in view of the above problems, the present inventors have found that by controlling physical properties of a thermally conductive film-like adhesive containing an epoxy resin (A), an epoxy resin curing agent (B), a polymer component (C), and an inorganic filler (D) such that a capillary rheometer viscosity under measurement conditions of a temperature of 120° C. and a load of 20 Kg is 1 to 1000 Pa·s, and a detection time of an exothermic peak in differential scanning calorimetry that performs holding at 120° C. is 15 minutes or longer, voids between the adhesive and a wiring board generated in a die attach step can be discharged with high efficiency even when the film-like adhesive is used as a die attach film and a thermal curing reaction after the die attach step is performed using a pressure oven set at a relatively low temperature. The present inventors further intensively conducted studies based on these findings, and have completed the present invention.

### Solution to Problem

As a result of conducting intensive studies to solve the above problems, the present inventors have found that the problems are solved by the following configurations.

[1]

A thermally conductive film-like adhesive containing:
an epoxy resin (A);
an epoxy resin curing agent (B);
a polymer component (C); and
an inorganic filler (D),
wherein a capillary rheometer viscosity at a temperature of 120° C. and a load of 20 Kg is 1 to 1000 Pa·s, and
wherein a detection time of an exothermic peak in differential scanning calorimetry that performs holding at 120° C. (hereinafter, referred to as “120° C. hold DSC measurement”) is 15 minutes or longer.
   [2]

The thermally conductive film-like adhesive described in [1],
wherein a proportion of the inorganic filler (D) to a total content of the epoxy resin (A), the epoxy resin curing agent (B), the polymer component (C), and the inorganic filler (D) is 30 to 70% by volume,
wherein the inorganic filler (D) has a sphericity of 0.6 to 1.0, and
wherein a cured product having a thermal conductivity of 1.0 W/m·K or more is provided after thermal curing.
   [3]

The thermally conductive film-like adhesive described in [1] or [2], having a thickness of 1 to 20 μm.

[4]

The thermally conductive film-like adhesive described in any one of [1] to [3], wherein the epoxy resin curing agent (B) contains an imidazole compound.

[5]

The thermally conductive film-like adhesive described in [4], wherein a content of the epoxy resin curing agent (B) per 100 parts by mass of the epoxy resin (A) is 0.5 to 7 parts by mass.

[6]

A dicing die attach film obtained by stacking a dicing film and the thermally conductive film-like adhesive described in any one of [1] to [5].

[7]

A method of producing a semiconductor package, including:
a first step of thermocompression-bonding the thermally conductive film-like adhesive described in any one of [1] to [5] to a back surface of a semiconductor wafer in which at least one semiconductor circuit is formed on a surface, and providing a dicing film via a layer of the thermally conductive film-like adhesive;
a second step of integrally dicing the semiconductor wafer and the adhesive layer to obtain a semiconductor chip with an adhesive layer on the dicing film;
a third step of removing the dicing film from the adhesive layer and thermocompression-bonding the semiconductor chip with an adhesive layer and a wiring board via the adhesive layer; and
a fourth step of thermally curing the adhesive layer.
   [8]

The method of producing a semiconductor package described in [7], wherein the first step is a step of thermocompression-bonding the dicing die attach film described in [6] to a back surface of the semiconductor wafer.

[9]

The method of producing a semiconductor package described in [7] or [8], wherein the thermally curing in the fourth step is performed in a pressure oven set at 100 to 150° C.

[10]

A semiconductor package obtained by the producing method described in any one of [7] to [9].

In the present invention, a numerical range represented using “to” means a range including numerical values at the critical points as a lower limit value and an upper limit value. For example, when “A to B” is described, the numerical range is “A or more and B or less”.

In the present invention, (meth)acryl means either or both of acryl and methacryl. The same applies to (meth)acrylate.

### Advantageous Effects of Invention

The thermally conductive film-like adhesive of the present invention can sufficiently advance a curing reaction under milder conditions, can effectively suppress residual voids between the adhesive and a wiring board in a semiconductor package to be obtained when used as a die attach film, and can obtain a semiconductor package excellent in heat releasing property inside the package.

In addition, according to the method of producing a semiconductor package of the present invention, the thermally conductive film-like adhesive of the present invention is used as an adhesive between a semiconductor chip and a wiring board, residual voids between the adhesive and a wiring board can be effectively suppressed, and a semiconductor package excellent in heat releasing property inside the package can be obtained.

In addition, in the semiconductor package of the present invention, the thermally conductive film-like adhesive of the present invention is used as an adhesive between a semiconductor chip and a wiring board, residual voids between the adhesive and the wiring board can be suppressed, and a heat releasing property inside the package is excellent.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of the method of producing a semiconductor package of the present invention.

FIG. 3 is a schematic longitudinal cross-sectional view illustrating a preferred embodiment of a third step of the method of producing a semiconductor package of the present invention.

FIG. 4 is a schematic longitudinal cross-sectional view illustrating a preferred embodiment of a step of connecting a bonding wire of the method of producing a semiconductor package of the present invention.

FIG. 5 is a schematic longitudinal cross-sectional view illustrating an example of an embodiment of multistacking of the method of producing a semiconductor package of the present invention.

FIG. 6 is a schematic longitudinal cross-sectional view illustrating another example of the embodiment of multistacking of the method of producing a semiconductor package of the present invention.

FIG. 7 is a schematic longitudinal cross-sectional view illustrating a preferred embodiment of a semiconductor package produced by the method of producing a semiconductor package of the present invention.

### DESCRIPTION OF EMBODIMENTS

### [Thermally Conductive Film-Like Adhesive]

A thermally conductive film-like adhesive (hereinafter, also simply referred to as film-like adhesive) of the present invention contains an epoxy resin (A), an epoxy resin curing agent (B), a polymer component (C), and an inorganic filler (D). In the thermally conductive film-like adhesive of the present invention, a capillary rheometer viscosity of the film-like adhesive under measurement conditions of a temperature of 120° C. and a load of 20 Kg is 1 to 1000 Pa·s. In addition, a detection time of an exothermic peak in measurement with a differential scanning calorimeter (DSC) that performs holding at 120° C. (120° C. hold DSC measurement) is 15 minutes or longer (900 seconds or longer).

In the present invention, the term “film” preferably refers to a form of a thin film having a thickness of 200 μm or less. The shape, size, and the like of the film in plan view are not particularly limited, and can be appropriately adjusted according to a use form.

The film-like adhesive of the present invention may be formed of a film-like adhesive alone, or may be a form obtained by bonding a release-treated substrate film to at least one surface of the film-like adhesive. The film-like adhesive of the present invention may be a form obtained by cutting a film into an appropriate size, or a form obtained by winding a film into a roll form.

### <Capillary Rheometer Viscosity>

In the present invention, the capillary rheometer viscosity is determined for a film-like adhesive before thermal curing under measurement conditions of a temperature of 120° C. and a load of 20 Kg using a heightened type flow tester. Specifically, the capillary rheometer viscosity can be determined by a method described in the section of [Examples] described later.

The capillary rheometer viscosity of the film-like adhesive of the present invention is 1 to 1000 Pa·s, preferably 2 to 900 Pa·s, more preferably 5 to 800 Pa·s, still more preferably 10 to 750 Pa·s, further still more preferably 20 to 700 Pa·s, further still more preferably 30 to 650 Pa·s, and also preferably 35 to 600 Pa·s. By setting the capillary rheometer viscosity within the above range, for example, when the film-like adhesive of the present invention is used as a die attach film, voids generated between the adhesive and a wiring board in a die attach step can be discharged with high efficiency even when a thermal curing reaction using a pressure oven is set to a relatively low temperature.

The capillary rheometer viscosity can be controlled by adjusting the type and blending amount of each raw material, adjusting the sphericity of the inorganic filler, and the like.

### <Detection Time of Exothermic Peak in 120° C. Hold DSC Measurement>

In the present invention, the detection time of an exothermic peak in 120° C. hold DSC measurement is a detection time of an exothermic peak obtained by raising a temperature of a film-like adhesive before thermal curing from room temperature (25° C.) to 120° C. at a temperature elevation rate of 30° C./min and then maintaining (holding) the temperature at 120° C. for 120 minutes using a differential scanning calorimeter. This detection time is a time (T3) obtained by subtracting an exothermic peak rise time (T1) from an exothermic peak end time (T2) (T3=T2−T1). Specifically, the detection time can be determined by a method described in the section of [Examples] described later.

The detection time of an exothermic peak of the film-like adhesive of the present invention in 120° C. hold DSC measurement is 15 minutes or longer, preferably 15 to 120 minutes, more preferably 16 to 100 minutes, still more preferably 18 to 80 minutes, also preferably 20 to 60 minutes, and also preferably 22 to 55 minutes. By controlling the detection time of an exothermic peak in the 120° C. hold DSC measurement within the above range, for example, when the film-like adhesive of the present invention is used as a die attach film, a curing reaction can be sufficiently advanced even when a thermal curing reaction using a pressure oven is set to a relatively low temperature, and voids generated between the adhesive and a wiring board in a die attach step can be discharged with high efficiency.

That is, in the film-like adhesive of the present invention, both the capillary rheometer viscosity under specific conditions and the detection time of an exothermic peak in 120° C. hold DSC measurement are controlled within specific ranges. As a result, when the film-like adhesive is used as a die attach film while a sufficient curing reaction under milder conditions is achieved, voids generated between the adhesive and a wiring board in a die attach step can be discharged over time with high efficiency even when a thermal curing reaction using a pressure oven is set to a relatively low temperature.

In the present invention or the specification, the “film-like adhesive before thermal curing” means a thermally conductive film-like adhesive which has not been exposed to a temperature condition of 25° C. or higher for 72 hours or more and has not been exposed to a temperature condition of higher than 30° C. after production of the film-like adhesive.

### <Thermal Conductivity>

The film-like adhesive of the present invention preferably provides a cured product having a thermal conductivity of 1.0 W/m·K or more after thermal curing. The thermal conductivity is more preferably 1.1 W/m·K or more, still more preferably 1.2 W/m·K or more, and further still more preferably 1.5 W/m·K or more. By setting the thermal conductivity after thermal curing to 1.0 W/m·K or more, heat inside a semiconductor package can be sufficiently dissipated to the outside when the film-like adhesive is used as a die attach film.

Here, “after thermal curing” of the film-like adhesive means a state in which a curing reaction of the film-like adhesive is completed. Specifically, “after thermal curing” is a state in which no reaction heat peak is observed when DSC measurement is performed at a temperature elevation rate of 10° C./min.

The thermal conductivity is determined by a heat flow meter method (in accordance with JIS-A1412 (2016)) using a thermal conductivity measurement device. Specifically, the thermal conductivity can be determined by a method described in the section of [Examples] described later.

In order to set the thermal conductivity of the film-like adhesive after thermal curing within the above range, the type and content of the inorganic filler (D) largely contribute. In addition, by also appropriately adjusting the types and contents of the epoxy resin (A), the epoxy resin curing agent (B), the polymer component (C), and the like, the thermal conductivity can be controlled.

### <Epoxy Resin (A)>

In the epoxy resin (A) used in the present invention, an epoxy equivalent is preferably 150 to 450 g/eq from a viewpoint of increasing a crosslinking density of a cured product, and as a result, increasing a contact probability between blended inorganic fillers (D) and a contact area between the inorganic fillers (D), thus providing a higher filling ratio. Note that, in the present invention, the epoxy equivalent refers to the number of grams of a resin containing 1 gram equivalent of epoxy group (g/eq).

The mass average molecular weight of the epoxy resin (A) is usually preferably less than 10,000, and more preferably 5,000 or less.

The mass average molecular weight is a value obtained by GPC (Gel Permeation Chromatography) analysis.

Examples of a skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among these skeletons, a triphenylmethane type, a bisphenol A type, a cresol novolac type, and an orthocresol novolac type are preferable from a viewpoint of being capable of obtaining a film-like adhesive having low resin crystallinity and favorable appearance.

The content of the epoxy resin (A) in the film-like adhesive of the present invention is preferably 3 to 40% by mass, more preferably 5 to 35% by mass, and still more preferably 7 to 35% by mass. By setting the content within the above preferable range, the thermal conductivity of a cured product of the film-like adhesive can be further improved, and generation of an oligomer component can be suppressed to make it difficult to change a film state (film tack property and the like).

### <Epoxy Resin Curing Agent (B)>

As the epoxy resin curing agent (B), for example, any curing agents such as amines, acid anhydrides, and polyhydric phenols can be used. In the present invention, a latent curing agent is preferably used from a viewpoint of providing a film-like adhesive that has a low melt viscosity, exhibits curability at a high temperature higher than a certain temperature, has rapid curability, and further has high storage stability that enables long-term storage at room temperature.

Examples of the latent curing agent include a dicyandiamide compound, an imidazole compound, a curing catalyst complex-based polyhydric phenol compound, a hydrazide compound, a boron trifluoride-amine complex, an aminimide compound, a polyamine salt, and modified products or microcapsules thereof.

In the present invention, an “A compound” means a “compound having an A skeleton”. For example, the “imidazole compound” includes not only imidazole itself but also includes a form in which at least some of hydrogen atoms of imidazole are replaced.

As the epoxy resin curing agent (B), the above curing agents may be used singly or in combination of two or more types thereof. The epoxy resin curing agent (B) preferably contains an imidazole compound, and is more preferably an imidazole compound from a viewpoint of having better latency (properties of exhibiting excellent stability at room temperature and curability by heating) and a higher curing rate.

In the film-like adhesive of the present invention, the content of the epoxy resin curing agent (B) per 100 parts by mass of the epoxy resin (A) is preferably 0.5 to 100 parts by mass, and more preferably 1 to 80 parts by mass. By setting the content to the above preferable lower limit or more, a curing time can be reduced. On the other hand, by setting the content to the preferable upper limit or less, failures in a reliability test conducted after the film-like adhesive is incorporated into a semiconductor, the failures being caused by excessive curing agent remaining in the film-like adhesive absorbing moisture, can be reduced.

When the epoxy resin curing agent (B) contains an imidazole compound, the content of the epoxy resin-curing agent (B) per 100 parts by mass of the epoxy resin (A) in the film-like adhesive is preferably 0.5 to 7 parts by mass, more preferably 1 to 6 parts by mass, still more preferably 1.2 to 5.5 parts by mass, further still more preferably 1.4 to 5 parts by mass, and further still more preferably 1.5 to 4 parts by mass. In this case, the epoxy resin curing agent (B) is preferably an imidazole compound.

### <Polymer Component (C)>

The polymer component (C) only needs to be a component that suppresses a film tack property at normal temperature (25° C.) (property that a film state is likely to change even by a little temperature change) and imparts sufficient adhesiveness and film formability (film forming property) when the film-like adhesive is formed. Examples of the polymer component (C) include:
a natural rubber, a butyl rubber, an isoprene rubber, a chloroprene rubber, an ethylene-vinyl acetate copolymer, an ethylene-(meth)acrylic acid copolymer, an ethylene-(meth)acrylic acid ester copolymer, a polybutadiene resin, a polycarbonate resin, a thermoplastic polyimide resin, and polyamide resins such as 6-nylon and 6,6-nylon;
a phenoxy resin, a (meth)acrylic resin, and polyester resins such as polyethylene terephthalate and polybutylene terephthalate;
a polyamideimide resin; and
a fluororesin. These polymer components (C) may be used singly, or in combination of two or more types thereof.

The polymer component (C) has a mass average molecular weight of 10,000 or more. An upper limit is not particularly limited, but is practically 5,000,000 or less, more preferably 700,000 or less, and also preferably 600,000 or less.

The mass average molecular weight of the polymer component (C) is a value obtained by GPC (Gel Permeation Chromatography) in terms of polystyrene. Hereinafter, a specific value of the mass average molecular weight of the polymer component (C) is also synonymous.

The glass transition temperature (Tg) of the polymer component (C) is preferably lower than 100° C., and more preferably lower than 90° C. A lower limit is preferably 0° C. or higher, and more preferably 10° C. or higher.

The glass transition temperature of the polymer component (C) is a glass transition temperature measured by DSC at a temperature elevation rate of 0.1° C./min. Hereinafter, a specific value of the glass transition temperature of the polymer component (C) is also synonymous.

In the present invention, with regard to the epoxy resin (A) and a resin which can have an epoxy group such as a phenoxy resin among the polymer components (C), a resin having an epoxy equivalent of 500 g/eq or less is classified into the epoxy resin (A), and a resin which does not correspond to the above resin is classified into the polymer component (C).

In the present invention, among these polymer components (C), at least one type of phenoxy resin is preferably used. The phenoxy resin has a structure similar to that of the epoxy resin (A), and thus has favorable compatibility with the epoxy resin (A). The phenoxy resin has a low resin melt viscosity and can exhibit excellent adhesiveness. In addition, the phenoxy resin has high heat resistance and small saturated water absorption, and thus is preferable from a viewpoint of ensuring reliability of a semiconductor package. Furthermore, the phenoxy resin is preferable in view of eliminating a tack property and brittleness at normal temperature.

The phenoxy resin can be obtained by a reaction of a bisphenol or a biphenol compound with an epihalohydrin such as epichlorohydrin, or a reaction of a liquid epoxy resin with a bisphenol or a biphenol compound.

In either of the reactions, the bisphenol or the biphenol compound is preferably a compound represented by the following Formula (A).

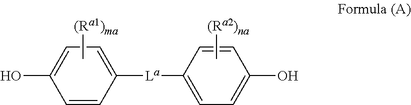

In Formula (A), L^{a} represents a single bond or a divalent linking group, and R^{a1} and R^{a2} each independently represent a substituent. ma and na each independently represent an integer of 0 to 4.

In L^{a}, the divalent linking group is preferably an alkylene group, a phenylene group, —O—, —S—, —SO—, —SO₂—, or a group in which an alkylene group and a phenylene group are combined.

The number of carbon atoms of the alkylene group is preferably 1 to 10, more preferably 1 to 6, still more preferably 1 to 3, particularly preferably 1 or 2, and most preferably 1.

The alkylene group is preferably —C(R^{α})(R^{β})—, in which R^{α} and R^{β} each independently represent a hydrogen atom, an alkyl group, or an aryl group. R^{α} and R^{β} may be bonded to each other to form a ring. R^{α} and R^{β} are each preferably a hydrogen atom or an alkyl group (for example, methyl, ethyl, isopropyl, n-propyl, n-butyl, isobutyl, hexyl, octyl, or 2-ethylhexyl). The alkylene group is, in particular, preferably —CH₂—, —CH(CH)—, or C(CH₃)₂—, more preferably —CH₂— or —CH(CH₃)—, and still more preferably —CH₂—.

The number of carbon atoms of the phenylene group is preferably 6 to 12, more preferably 6 to 8, and still more preferably 6. Examples of the phenylene group include p-phenylene, m-phenylene, and o-phenylene, and p-phenylene and m-phenylene are preferable.

The group in which an alkylene group and a phenylene group are combined is preferably an alkylene-phenylene-alkylene group, and more preferably —C(R^{α})(R^{β})-phenylene-C(R^{α})(R^{β})—.

The ring formed by bonding of R^{α} and R^{β} is preferably a 5- or 6-membered ring, more preferably a cyclopentane ring or a cyclohexane ring, and still more preferably a cyclohexane ring.

L^{a} is preferably a single bond, an alkylene group, —O—, or —SO₂—, and more preferably an alkylene group.

In R^{a1} and R^{a2}, the substituent is preferably an alkyl group, an aryl group, an alkoxy group, an alkylthio group, or a halogen atom, and more preferably an alkyl group, an aryl group, or a halogen atom, and still more preferably an alkyl group.

ma and na are each preferably 0 to 2, more preferably 0 or 1, and still more preferably 0.

Examples of the bisphenol or the biphenol compound include:
bisphenol A, bisphenol AD, bisphenol AP, bisphenol AF, bisphenol B, bisphenol BP, bisphenol C, bisphenol E, bisphenol F, bisphenol G, bisphenol M, bisphenol S, bisphenol P, bisphenol PH, bisphenol TMC, and bisphenol Z; and
4,4′-biphenol, 2,2′-dimethyl-4,4′-biphenol, 2,2′,6,6′-tetramethyl-4,4′-biphenol, and cardo skeleton type bisphenol,
among which bisphenol A, bisphenol AD, bisphenol C, bisphenol E, bisphenol F, and 4,4′-biphenol are preferable, bisphenol A, bisphenol E, and bisphenol F are more preferable, and bisphenol A is particularly preferable.

Meanwhile, the liquid epoxy resin is preferably diglycidyl ether of an aliphatic diol compound, and is more preferably a compound represented by the following Formula (B).

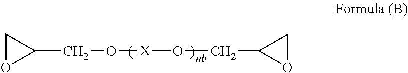

In Formula (B), X represents an alkylene group, and nb represents an integer of 1 to 10.

The number of carbon atoms of the alkylene group is preferably 2 to 10, more preferably 2 to 8, still more preferably 3 to 8, particularly preferably 4 to 6, and most preferably 6.

Examples of the alkylene group include ethylene, propylene, butylene, pentylene, hexylene, and octylene. Ethylene, trimethylene, tetramethylene, pentamethylene, heptamethylene, hexamethylene, and octamethylene are preferable.

nb is preferably 1 to 6, more preferably 1 to 3, and still more preferably 1.

Here, when nb is 2 to 10, X is preferably ethylene or propylene, and more preferably ethylene.

Examples of the aliphatic diol compound in diglycidyl ether include ethylene glycol, propylene glycol, diethylene glycol, triethylene glycol, polyethylene glycol, 1,3-propanediol, 1,4-butanediol, 1,5-heptanediol, 1,6-hexanediol, 1,7-pentanediol, and 1,8-octanediol.

In the above reactions, the phenoxy resin is a phenoxy resin obtained by reacting a single bisphenol or biphenol compound, or aliphatic diol compound, or may be a phenoxy resin obtained by mixing and reacting two or more types of bisphenols or biphenol compounds, or aliphatic diol compounds. Examples thereof include a reaction of diglycidyl ether of 1,6-hexanediol with a mixture of bisphenol A and bisphenol F.

The phenoxy resin in the present invention is preferably a phenoxy resin obtained by a reaction of a liquid epoxy resin with a bisphenol or a biphenol compound, and more preferably a phenoxy resin having a repeating unit represented by the following Formula (I).

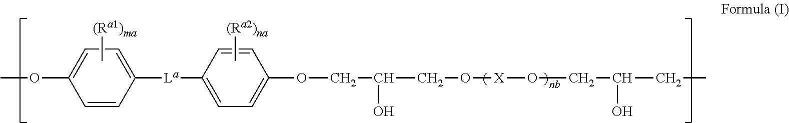

In Formula (I), L^{a}, R^{a1}, R^{a2}, ma, and na are synonymous with L^{a}, R^{a1}, R^{a2}, ma, and na in Formula (A), and preferable ranges thereof are also synonymous. X and nb are synonymous with X and nb in Formula (B), and preferable ranges thereof are also synonymous.

In the present invention, a polymer of bisphenol A and diglycidyl ether of 1,6-hexanediol is preferable among these substances.

The mass average molecular weight of the phenoxy resin is preferably 10,000 or more, and more preferably 10,000 to 100,000.

The amount of epoxy group remaining in a small amount in the phenoxy resin is preferably 5,000 g/eq or more in terms of epoxy equivalent.

The glass transition temperature (Tg) of the phenoxy resin is preferably lower than 100° C., and more preferably lower than 90° C. A lower limit is preferably 0° C. or higher, and more preferably 10° C. or higher.

The phenoxy resin may be synthesized by the above method, or a commercially available product may be used. Examples of the commercially available product include YX7180 (trade name: bisphenol F+1,6-hexanediol diglycidyl ether type phenoxy resin, manufactured by Mitsubishi Chemical Corporation), 1256 (trade name: bisphenol A type phenoxy resin, manufactured by Mitsubishi Chemical Corporation), YP-50 (trade name: bisphenol A type phenoxy resin, manufactured by NSCC Epoxy Manufacturing Co., Ltd.), YP-70 (trade name: bisphenol A/F type phenoxy resin, manufactured by NSCC Epoxy Manufacturing Co., Ltd.), FX-316 (trade name: bisphenol F type phenoxy resin, manufactured by NSCC Epoxy Manufacturing Co., Ltd.), and FX-280S (trade name: cardo skeleton type phenoxy resin, manufactured by NSCC Epoxy Manufacturing Co., Ltd.), 4250 (trade name: bisphenol A type/F type phenoxy resin, manufactured by Mitsubishi Chemical Corporation), and the like.

As the (meth)acrylic resin, a normal resin composed of a (meth)acrylic copolymer is used.

The mass average molecular weight of the (meth)acrylic copolymer is preferably 10,000 to 2,000,000, and more preferably 100,000 to 1,500,000. By setting the mass average molecular weight within the above preferable range, a tack property can be reduced, and an increase in melt viscosity can also be suppressed.

The glass transition temperature of the (meth)acrylic copolymer is preferably within a range of −10° C. to 50° C., more preferably within a range of 0° C. to 40° C., and still more preferably within a range of 0° C. to 30° C. By setting the glass transition temperature within the above preferable range, a tack property can be reduced, and generation of voids between a semiconductor wafer and the film-like adhesive and the like can be suppressed.

Examples of the (meth)acrylic resin include poly(meth)acrylic acid ester-based resins and derivatives thereof. Examples thereof include copolymers containing, as a monomer component, 2-hydroxyethyl acrylate, 2-hydroxyethyl methacrylate, 2-hydroxypropyl acrylate, 2-hydroxypropyl methacrylate, acrylic acid, methacrylic acid, itaconic acid, glycidylmethacrylate, and glycidylacrylate.

Examples of the monomer component that is used also include: (meth)acrylic acid esters having a cyclic skeleton, such as (meth)acrylic acid cydoalkyl ester, (meth)acrylic acid benzyl ester, isobornyl (meth)acrylate, dicydopentanyl (meth)acrylate, dicyclopentenyl (meth)acrylate, and dicydopentenyloxyethyl (meth)acrylate, and imide (meth)acrylate; and (meth)acrylic acid alkyl esters having 1 to 18 carbon atoms in an alkyl group, such as methyl(meth)acrylate, ethyl(meth)acrylate, propyl(meth)acrylate, and butyl(meth)acrylate.

Furthermore, these monomer components may be copolymerized with vinyl acetate, (meth)acrylonitrile, styrene, or the like. A (meth)acrylic resin having a hydroxy group is preferable because compatibility with an epoxy resin is favorable.

The content of the polymer component (C) per 100 parts by mass of the epoxy resin (A) is preferably 1 to 40 parts by mass, more preferably 5 to 35 parts by mass, and still more preferably 10 to 30 parts by mass. By setting the content within such a range, rigidity and flexibility of the thermally conductive film-like adhesive before curing can be adjusted. In addition, the state of the film is favorable (film tack property is reduced), and film brittleness can also be suppressed.

### <Inorganic Filler (D)>

As the inorganic filler (D), an inorganic filler that can be usually used for a die attach film can be used without particular limitation.

Examples of the inorganic filler (D) include various types of inorganic powder made of
ceramics such as silica, clay, gypsum, calcium carbonate, barium sulfate, alumina (aluminum oxide), beryllium oxide, magnesium oxide, silicon carbide, silicon nitride, aluminum nitride, and boron nitride;
metals or alloys, such as aluminum, copper, silver, gold, nickel, chromium, tin, zinc, palladium, and solder, and
carbons such as carbon nanotube and graphene.

The average particle diameter (d50) of the inorganic filler (D) is not particularly limited, and is preferably 0.01 to 10.0 μm, more preferably 0.1 to 7.0 μm, and still more preferably 0.3 to 6.0 μm from a viewpoint of enhancing die attach performance while suppressing formation of any jig mark. The average particle diameter (d50) is a so-called median diameter, and refers to a particle diameter at which the cumulative volume is 50% when the particle size distribution is measured by a laser diffraction scattering method and the total volume of the particles is defined as 100% in a cumulative distribution.

The sphericity of the inorganic filler (D) is appropriately set in order to control the film-like adhesive so as to have a desired capillary rheometer viscosity. For example, when the sphericity is 0.6 to 1.0, the capillary rheometer viscosity of the film-like adhesive can be suppressed even when a large amount of the inorganic filler is blended to some extent. The sphericity of the inorganic filler (D) is preferably 0.65 to 0.99, more preferably 0.80 to 0.99, and also preferably 0.90 to 0.99 from this viewpoint. The sphericity is determined based on the area and the perimeter of the inorganic filler (D) observed with a scanning electron microscope. Specifically, the sphericity can be determined by referring to a method described in [Examples] described later.

The Mohs hardness of the inorganic filler is not particularly limited, and is preferably 2 or more and more preferably 2 to 9 from a viewpoint of enhancing die attach performance while suppressing occurrence of any jig mark. The Mohs hardness can be measured with a Mohs hardness meter.

The inorganic filler (D) preferably contains an inorganic filler having a thermal conductivity of 12 W/m·K or more. The inorganic filler having a thermal conductivity of 12 W/m·K or more is a particle made of a thermally conductive material or a particle whose surface is coated with the thermally conductive material. The thermal conductivity of the thermally conductive material is preferably 12 W/m·K or more, and more preferably 30 W/m·K or more.

When the thermal conductivity of the thermally conductive material is the preferable lower limit or more, the amount of the inorganic filler (D) blended in order to obtain a desired thermal conductivity can be reduced. This suppresses an increase in the melt viscosity of the adhesive film, and improves an embedding property of the film into unevenness of a substrate at the time of compression bonding to the substrate, thus enabling to suppress generation of voids.

In the present invention, the thermal conductivity of the thermally conductive material means a thermal conductivity at 25° C., and a literature value for each material can be used. In a case where there is no description in literatures, for example, a value measured in accordance with JIS R 1611 (2010) can be used in a case of ceramics, and a value measured in accordance with JIS H 7801 (2005) can be used in a case of metals in substitution for literature values.

Examples of the inorganic filler (D) include thermally conductive ceramics, and preferred examples thereof include alumina particles (thermal conductivity: 36 W/m·K), aluminum nitride particles (thermal conductivity: 150 to 290 W/m·K), boron nitride particles (thermal conductivity: 60 W/m·K), zinc oxide particles (thermal conductivity: 54 W/m·K), a silicon nitride filler (thermal conductivity: 27 W/m·K), silicon carbide particles (thermal conductivity: 200 W/m·K), and magnesium oxide particles (thermal conductivity: 59 W/m·K).

In particular, alumina particles having high thermal conductivity are preferable in terms of dispersibility and availability. Aluminum nitride particles and boron nitride particles are preferable from a viewpoint of having a higher thermal conductivity than alumina particles. In the present invention, alumina particles and aluminum nitride particles are preferable among these particles.

Examples of the inorganic filler (D) also include metal particles having a higher thermal conductivity than ceramics and particles surface-coated with metal. Preferred examples thereof include a single metal filler such as silver (thermal conductivity: 429 W/m·K), nickel (thermal conductivity: 91 W/m·K), or gold (thermal conductivity: 329 W/m·K), and polymer particles such as acrylic resin particles or silicone resin particles whose surfaces are coated with these metals.

In the present invention, gold or silver particles are more preferable from a viewpoint of, in particular, high thermal conductivity and oxidation resistance deterioration.

The inorganic filler (D) may be subjected to surface treatment or surface modification. Examples of such surface treatment or surface modification include a silane coupling agent, phosphoric acid, a phosphoric acid compound, and a surfactant. In addition to the items described in the present specification, for example, descriptions of a silane coupling agent, phosphoric acid or a phosphoric acid compound, and a surfactant in a section of a thermally conductive filler in WO-A-2018/203527 or a section of an aluminum nitride filler in WO-A-2017/158994 can be applied.

Examples of a method of blending the inorganic filler (D) to resin components such as the epoxy resin (A), the epoxy resin curing agent (B), and the polymer component (C) include a method in which a powder inorganic filler and, if necessary, a silane coupling agent, phosphoric acid or a phosphoric acid compound, and a surfactant are directly blended (integral blending method), and a method in which a slurry inorganic filler obtained by dispersing an inorganic filler treated with a surface treatment agent such as a silane coupling agent, phosphoric acid or a phosphoric acid compound, or a surfactant in an organic solvent is blended.

A method of treating the inorganic filler (D) with a silane coupling agent is not particularly limited. Examples thereof include a wet method of mixing the inorganic filler (D) and a silane coupling agent in a solvent, a dry method of treating the inorganic filler (D) and a silane coupling agent in a gas phase, and the integral blending method.

In particular, the aluminum nitride particles contribute to high thermal conductivity, but tend to generate ammonium ions due to hydrolysis. It is therefore preferable that the aluminum nitride particles are used in combination with a phenol resin having a low moisture absorption rate or hydrolysis is suppressed by surface modification. As an aluminum nitride surface modification method, a method of providing a surface layer with an oxide layer of aluminum oxide to improve water proofness and then preforming surface treatment with phosphoric acid or a phosphoric acid compound to improve affinity with a resin is particularly preferable.

The silane coupling agent is a compound in which at least one hydrolyzable group such as an alkoxy group or an aryloxy group is bonded to a silicon atom. In addition to these groups, an alkyl group, an alkenyl group, or an aryl group may be bonded to the silicon atom. The alkyl group preferably has a substituent of an amino group, an alkoxy group, an epoxy group, or a (meth)acryloyloxy group, and more preferably has a substituent of an amino group (preferably, a phenylamino group), an alkoxy group (preferably, a glycidyloxy group), or a (meth)acryloyloxy group.

Examples of the silane coupling agent include 2-(3,4-epoxycyclohexyl) ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, and 3-methacryloyloxypropyltriethoxysilane.

The silane coupling agent or the surfactant is preferably contained in an amount of 0.1 to 2.0 parts by mass per 100 parts by mass of the inorganic filler (D).

By setting the content of the silane coupling agent or the surfactant within the above preferable range, it is possible to suppress peeling at an adhesion interface due to volatilization of an excessive silane coupling agent and surfactant, for example, in a semiconductor assembling heating step (for example, a reflow step) while suppressing aggregation of the inorganic filler (D). As a result, generation of voids can be suppressed, and adhesiveness can be improved.

The shape of the inorganic filler (D) is not particularly limited, and examples thereof include a flake shape, a needle shape, a filament shape, a spherical shape, and a scale shape. A spherical particle is preferable from a viewpoint of achieving higher filling and fluidity.

In the present invention, the proportion of the inorganic filler (D) in the total content of the epoxy resin (A), the epoxy resin curing agent (B), the polymer component (C), and the inorganic filler (D) is preferably 30 to 70% by volume. By setting the content proportion of the inorganic filler (D) within the above range, a desired thermal conductivity and melt viscosity are easily imparted to the film-like adhesive, a heat dissipation effect from a semiconductor package can be sufficiently exhibited, and generation of voids in a die attach step can be further suppressed while protrusion failure of the film-like adhesive is prevented. In addition, an effect of relaxing internal stress generated in a semiconductor package during thermal change can be enhanced, which also contributes to improvement of an adhesive force.

The proportion of the inorganic filler (D) in the total content of the components (A) to (D) is preferably 30 to 60% by volume, and more preferably 30 to 50% by volume.

The content (% by volume) of the inorganic filler (D) can be calculated from the content mass and the specific gravity of each of the components (A) to (D).

### <Other Components>

In addition to the epoxy resin (A), the epoxy resin curing agent (B), the polymer component (C), and the inorganic filler (D), the film-like adhesive of the present invention may further contain additives such as an organic solvent (MEK (Methyl ethyl ketone) or the like), an ion trapping agent (ion capturing agent), a viscosity adjusting agent, an antioxidant, a flame retardant, a coloring agent, and a stress relaxing agent such as a butadiene-based rubber or a silicone rubber, as long as the effect of the present invention is not inhibited. For example, description of another additive in WO-A-2017/158994 can be applied.

The proportion of the total content of the epoxy resin (A), the epoxy resin curing agent (B), the polymer component (C), and the inorganic filler (D) in the film-like adhesive of the present invention is not particularly limited as long as the film-like adhesive of the present invention can be obtained. The proportion can be, for example, 60 to 95% by mass, and is preferably 70 to 90% by mass.

### [Method of Producing Film-Like Adhesive]

One preferred embodiment of the method of producing a film-like adhesive of the present invention is a method in which components of a film-like adhesive are usually uniformly mixed in a solvent to prepare a composition (composition for forming a film-like adhesive), this composition is applied onto one surface of a release-treated substrate film, and the solvent is removed by heating and drying.

As the release-treated substrate film, any release-treated substrate film that functions as a cover film of an obtained film-like adhesive can be used, and a normal film can be appropriately employed. Examples thereof include release-treated polypropylene (PP), release-treated polyethylene (PE), and release-treated polyethylene terephthalate (PET). A normal method can be appropriately employed as an application method, and examples thereof include methods using a roll knife coater, a gravure coater, a die coater, and a reverse coater.

The thickness of the film-like adhesive of the present invention thus obtained is preferably 1 to 200 μm, more preferably 1 to 100 μm, still more preferably 1 to 50 μm, also preferably 1 to 30 μm, and also preferably 1 to 20 μm. The thickness is preferably 2 μm or more, and also preferably 3 μm or more. By controlling the thickness of the film-like adhesive as described above, for example, when the film-like adhesive is used as a die attach film, the film-like adhesive can be more sufficiently embedded in unevenness of a surface of a wiring board or a semiconductor chip, and is also excellent in thermal conductivity. In addition, an organic solvent can be sufficiently removed at the time of production, and a form exhibiting an appropriate film tack property can be obtained.

The thickness of the film-like adhesive can be measured by a contact type linear gauge method (desk-top contact type thickness measurement apparatus).

In the film-like adhesive of the present invention, the arithmetic average roughness Ra of at least one surface thereof (that is, at least one surface to be bonded to an adherend) is preferably 3.0 μm or less, and the arithmetic average roughness Ra of both surfaces is also preferably 3.0 μm or less.

The arithmetic average roughness Ra is more preferably 2.0 μm or less, and still more preferably 1.5 μm or less. A lower limit is not particularly limited, but is practically 0.1 μm or more.

### [Dicing Die Attach Film]

The film-like adhesive of the present invention is suitable as a die attach film used in a semiconductor production process. Therefore, a dicing die attach film (dicing die bond film) can be formed by stacking a dicing film and the film-like adhesive of the present invention.

For example, a coating liquid containing a temporary-adhesive is applied onto a release-treated release liner and dried to form a dicing film, and then the dicing film and a substrate film are bonded. Thus, a stacked body in which the substrate film, the dicing film, and the release liner are stacked in this order is obtained. Separately from this, a composition for forming a die attach film (the above composition for forming a film-like adhesive) is applied onto a release film (synonymous with a release liner, but the expression is changed here for convenience), and dried to form a die attach film on the release film. Then, the dicing film and the die attach film are bonded in such a manner that the dicing film exposed by peeling off the release liner and the die attach film are in contact with each other. Thus, a dicing die attach film in which the substrate film, the dicing film, the die attach film, and the release film are stacked in this order can be obtained.

Bonding of the dicing film and the die attach film is preferably performed under a pressurized condition.

As the temporary-adhesive constituting the dicing film, general temporary-adhesives used for application to the dicing film, for example, an acrylic temporary-adhesive, a rubber-based temporary-adhesive, or the like can be appropriately used. Among these, the dicing film is preferably energy ray-curable. Regarding the configuration of the dicing film, for example, descriptions of JP-A-2010-232422, Japanese Patent No. 2661950, JP-A-2002-226796, and JP-A-2005-303275 can be used as a reference.

In the bonding of the dicing film and the die attach film, the shape of the dicing film is not particularly limited as long as an opening of a ring frame can be covered, but is preferably a circular shape. The shape of the die attach film is not particularly limited as long as a back surface of a wafer can be covered, but is preferably a circular shape. The dicing film is preferably larger than the die attach film, and preferably has a shape having a portion in which the temporary-adhesive layer is exposed around the adhesive layer. As described above, it is preferable to bond the dicing film and the die attach film which are cut into desired shapes.

The dicing die attach film prepared as described above is used by peeling the release film off upon use.

### [Semiconductor Package and Method of Producing the Same]

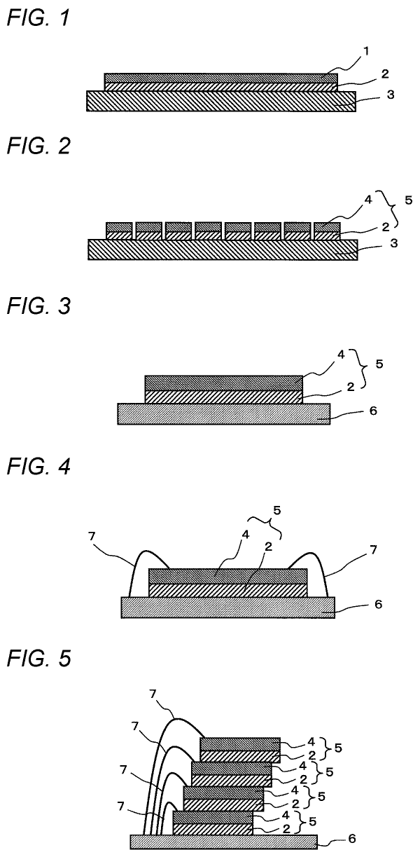

Then, preferred embodiments of a semiconductor package of the present invention and a method of producing the same will be described in detail with reference to the drawings. Note that, in the descriptions and drawings below, the same reference numerals are given to the same or corresponding components, and overlapping descriptions will be omitted. FIGS. 1 to 7 are schematic longitudinal cross-sectional views each illustrating a preferred embodiment of each step of the method of producing a semiconductor package of the present invention.

In the method of producing a semiconductor package of the present invention, first, as a first step, as illustrated in FIG. 1, the film-like adhesive of the present invention is thermocompression-bonded to a back surface (that is, a surface of the semiconductor wafer 1 on which the semiconductor circuit is not formed) of a semiconductor wafer 1 in which at least one semiconductor circuit is formed on a surface to provide an adhesive layer 2, and then the semiconductor wafer 1 and a dicing film 3 are provided with the adhesive layer 2 interposed therebetween. At this time, the stacked body in which the adhesive layer 2 and the dicing film 3 are combined may also be thermocompression-bonded simultaneously. A condition for thermocompression bonding is not particularly limited as long as the effect of the present invention is not impaired due to thermal curing of the epoxy resin (A), and examples thereof include a condition of a temperature of 70° C. and a pressure of 0.3 MPa.

As the semiconductor wafer 1, a semiconductor wafer in which at least one semiconductor circuit is formed on a surface can be appropriately used. Examples thereof include a silicon wafer, a SiC wafer, and a GaN wafer. As the adhesive layer 2, one layer of the thermally conductive film-like adhesive of the present invention may be used alone, or two or more layers thereof may be stacked and used. As a method of providing such an adhesive layer 2 on a back surface of the wafer 1, a method capable of stacking the film-like adhesive on the back surface of the semiconductor wafer 1 can be appropriately employed. Examples thereof include a method of bonding the film-like adhesive to the back surface of the semiconductor wafer 1 and then, in a case of stacking two or more layers, sequentially stacking the film-like adhesive to a desired thickness, and a method of stacking the film-like adhesive to a desired thickness in advance and then bonding the resulting stacked body to the back surface of the semiconductor wafer 1. An apparatus used when such an adhesive layer 2 is provided on the back surface of the semiconductor wafer 1 is not particularly limited. For example, a normal apparatus such as a roll laminator or a manual laminator can be appropriately used.

Then, as a second step, the semiconductor wafer 1 and the adhesive layer 2 are integrally diced as illustrated in FIG. 2. Thus, a semiconductor chip 5 with an adhesive layer, including the semiconductor wafer 1 and the adhesive layer 2 is obtained on the dicing film 3. The dicing film 3 is not particularly limited, and a normal dicing film can be used. Furthermore, an apparatus used for dicing is not particularly limited, and a normal dicing apparatus can be used.

Then, as a third step, as illustrated in FIG. 3, the dicing film 3 is removed from the adhesive layer 2, and the semiconductor chip 5 with an adhesive layer and a wiring board 6 are thermocompression-bonded to each other via the adhesive layer 2 to mount the semiconductor chip 5 with an adhesive layer on the wiring board 6 (die attach step). As the wiring board 6, a substrate in which a semiconductor circuit is formed on a surface can be appropriately used. Examples thereof include a print circuit board (PCB), various lead frames, and a substrate on a surface of which electronic components such as a resistive element and a capacitor are mounted.

A method of mounting the semiconductor chip 5 with an adhesive layer on such a wiring board 6 is not particularly limited. A normal method that enables to bond the semiconductor chip 5 with an adhesive layer to the wiring board 6 or an electronic component mounted on a surface of the wiring board 6 by utilizing the adhesive layer 2 can be appropriately employed. Examples of such a mounting method include normal heating and pressurizing methods such as a method using a mounting technique using a flip chip bonder having a heating function from an upper part, a method using a die bonder having a heating function only from a lower part, and a method using a laminator.

As described above, mounting the semiconductor chip 5 with an adhesive layer on the wiring board 6 via the adhesive layer 2 formed of the film-like adhesive of the present invention allows the film-like adhesive to conform to unevenness on the wiring board 5, formed due to an electronic component, and therefore the semiconductor chip 4 and the wiring board 6 can be fixed in close contact with each other.

Then, as a fourth step, the film-like adhesive of the present invention is thermally cured. The temperature for thermal curing is not particularly limited as long as it is a temperature equal to or higher than the thermal curing start temperature of the film-like adhesive of the present invention. The temperature varies depending on the types of the epoxy resin (A), the polymer component (C), and the epoxy resin curing agent (B) to be used. Although it cannot be said unconditionally, it is desirable to cure the film-like adhesive in a lower temperature range (for example, 100 to 150° C.) in consideration of damage to a semiconductor package and energy efficiency. When the heating temperature using a pressure oven is in the above low temperature range, a curing reaction may be insufficient due to insufficient action of a curing catalyst. Therefore, it is preferable to use a curing agent capable of sufficiently advancing the curing reaction even in this low temperature range. When such a curing agent is used, the curing reaction proceeds quickly, and therefore a time until an end of curing is shortened. Under such circumstances, the present inventors have found that when a specific amount of a specific curing catalyst is used, the curing reaction in the above low temperature range can be sufficiently advanced while moderately suppressing a curing reaction rate. Due to such curing reaction characteristics, voids generated between the adhesive layer 2 and the wiring board 6 in the die attach step can be sufficiently discharged over time while the thermal curing reaction is advanced using a pressure oven in a relatively low temperature range of about 100 to 150° C.

Then, in the method of producing a semiconductor package of the present invention, it is preferable to connect the wiring board 6 and the semiconductor chip 5 with an adhesive layer via a bonding wire 7 as illustrated in FIG. 4. Such a connection method is not particularly limited, and a normal method, for example, a wire bonding method or a TAB (Tape Automated Bonding) method can be appropriately employed.

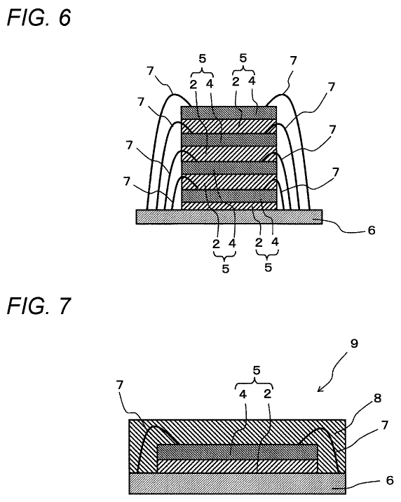

In addition, by thermocompression-bonding another semiconductor chip 4 to a surface of the mounted semiconductor chip 4, performing thermal curing, and connecting the semiconductor chips 4 again to the wiring board 6 by a wire bonding method, a plurality of semiconductor chips 4 can be stacked. For example, there is a method of stacking the semiconductor chips in a shifted manner as illustrated in FIG. 5, or a method of stacking semiconductor chips while embedding the bonding wire 7 by thickening the second and subsequent adhesive layers 2 as illustrated in FIG. 6.

In the method of producing a semiconductor package of the present invention, it is preferable to seal the wiring board 6 and the semiconductor chip 5 with an adhesive layer using a sealing resin 8 as illustrated in FIG. 7. In this way, a semiconductor package 9 can be obtained. The sealing resin 8 is not particularly limited, and a normal sealing resin that can be used for production of a semiconductor package can be used. In addition, a sealing method using the sealing resin 8 is not particularly limited, and a normal method can be employed.

The method of producing a semiconductor package of the present invention can provide the adhesive layer 2 that suppresses generation of voids after a die attach step even in a form of a thin film, and furthermore, can exhibit high adhesive force with an adherend. In addition, it is possible to efficiency release heat generated on a surface of the semiconductor chip 4 to the outside of the semiconductor package 9 by exhibiting excellent thermal conductivity after thermal curing.

### EXAMPLES

Hereinafter, the present invention will be described in more detail based on Examples and Comparative Examples. However, the present invention is not limited to the following Examples.

In Examples and Comparative Examples, room temperature means 25° C., MEK is methyl ethyl ketone, and PET is polyethylene terephthalate.

### [Measurement and Analysis]

### <Sphericity of Inorganic Filler>

A small amount of each of various types of inorganic fillers was placed on a glass plate, and observed with a scanning electron microscope (model number FlexSEM 1000II, manufactured by Hitachi High-Tech Co., Ltd.) at a magnification of 10,000 times. Based on the observation image, the area and the perimeter of each particle of the inorganic filler were measured using particle analysis software, and the degree of unevenness of each particle of the inorganic filler was calculated by the following formulas (1) and (2).

Degree of unevenness of inorganic filler=(perimeter²×area)×¼π (1)

Sphericity of inorganic filler=1/(degree of unevenness of inorganic filler) (2)

Ten particles of the inorganic filler in the observation image were randomly observed, and an arithmetic average value of the sphericity of the ten particles of the inorganic filler was defined as the sphericity of the inorganic filler blended in the film-like adhesive.

### <Measurement of Capillary Rheometer Viscosity>

The thermally conductive film-like adhesive obtained in each of Examples and Comparative Examples was cut into 10 g, and processed into a cylindrical shape having a height of 25 mm×a diameter of 10 mm using a simple pressing machine. This processed sample was placed in a cylinder warmed to 120° C. of a heightened type flow tester (CFT-500EX) manufactured by Shimadzu Corporation, and left for 20 seconds. Then, a capillary rheometer viscosity was measured under measurement conditions of a temperature of 120° C. and a load of 20 kg (a weight of 1.5 kg was placed).

### <Detection Time of Exothermic Peak in 120° C. Hold DSC Measurement>

The thermally conductive film-like adhesive obtained in each of Examples and Comparative Examples was cut into 10 mg, and the temperature was measured by raising the temperature from room temperature (25° C.) to 120° C. at a temperature elevation rate of 30° C./min, and then held (maintained) at 120° C. for 120 minutes with a differential scanning calorimeter (model number DSC 7000, manufactured by Hitachi High-Tech Science Corporation). From an obtained exothermic peak, an exothermic peak rise time T1 and an exothermic peak end time T2 were determined using thermal analysis software (software name: SOFTWARE FOR NEXTA), and a detection time T3 of the exothermic peak was obtained.

T3=T2−T1
T1: Time of intersection between tangent of rising portion of exothermic peak and baseline
T2: Time of intersection between tangent of falling portion of exothermic peak and baseline
   <Evaluation of Void after Curing>

The thermally conductive film-like adhesive obtained in each of Examples and Comparative Examples was first bonded to one surface of a dummy silicon wafer (8 inch size, thickness 100 μm) using a manual laminator (trade name: FM-114, manufactured by Technovision, Inc.) at a temperature of 70° C. and a pressure of 0.3 MPa. A release film on a surface of the thermally conductive film-like adhesive opposite to the dummy silicon wafer was peeled off, and a dicing film (trade name: K-13, manufactured by Furukawa Electric Co., Ltd.) and a dicing frame (trade name: DTF2-8-1H001, manufactured by DISCO Corporation) were bonded onto a surface of the thermally conductive film-like adhesive opposite to the dummy silicon wafer using the same manual laminator at room temperature (25° C.) and a pressure of 0.3 MPa. Then, dicing was performed from the dummy silicon wafer side to form squares each having a size of 10 mm×10 mm using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation), thus obtaining a dummy chip with an adhesive layer.

Then, the obtained dummy chip with an adhesive layer was irradiated with ultraviolet rays from a back surface side of the wafer using an ultraviolet ray irradiator (trade name: RAD-2000F/8, manufactured by Lintec Corporation, irradiation amount: 200 mJ/cm²), and was thermocompression-bonded to a mounting surface side of an organic substrate (BT resin-based, surface unevenness Rz value 5 μm, manufactured by Kyoden Co., Ltd.) having surface unevenness using a die bonder (trade name: DB-800, manufactured by Hitachi High-Tech Corporation) under the following pickup conditions and die attach conditions. Thereafter, the adhesive layer of the dummy chip with an adhesive layer thermocompression-bonded onto the substrate was thermally cured in a pressure oven (trade name: VTS-60A, manufactured by APT) under the following pressure curing conditions. Presence or absence of voids at an interface between the adhesive layer and the mounting surface of the organic substrate was observed using an ultrasonic flaw detector (SAT) (FS300III, manufactured by Hitachi Power Solutions Co., Ltd.). A die attach property was evaluated based on the following criteria.

Pickup Conditions
Number of needles 5 (350R), needle height 200 μm, pickup timer 100 msec

### Die Attach Conditions

120° C., pressure 0.1 MPa (load 400 gf), time 1.0 second

### Pressure Curing Conditions

120° C., pressure 7.0 f/cm², time 30 minutes, 60 minutes, or 90 minutes

Evaluation Criteria
AAA: No voids are observed in all of the 24 dummy chips mounted for a pressure curing time of 30 minutes.
AA: No voids are observed in all of the 24 dummy chips mounted for a pressure curing time of 60 minutes although this case does not correspond to the above AAA.
A: No voids are observed in all of the 24 dummy chips mounted for a pressure curing time of 90 minutes although this case does not correspond to the above AAA or AA.
B: There are one to five dummy chips having voids generated out of the 24 dummy chips mounted for a pressure curing time of 90 minutes.
C: There are six or more dummy chips having voids generated out of the 24 dummy chips mounted for a pressure curing time of 90 minutes.

### <Thermal Conductivity>

A square piece having a side of 50 mm or more was cut out from the prepared thermally conductive film-like adhesive, and the cut samples were superimposed to obtain an adhesive layer stacked body having a thickness of 5 mm or more.

This sample was placed on a disk-shaped mold with a diameter of 50 mm and a thickness 5 mm, heated at a temperature of 150° C. and a pressure of 2 MPa for 10 minutes using a compression press molding machine, and then taken out. Thereafter, the sample was further heated in a dryer at a temperature of 180° C. for one hour to thermally cure the adhesive layer. Thus, a disk-shaped test piece having a diameter of 50 mm and a thickness of 5 mm was obtained.

A thermal conductivity (W/(m·K)) was measured for this test piece using a thermal conductivity measurement apparatus (trade name: HC-110, manufacture by Eko Instruments Co., Ltd) according to a heat flow meter method (in accordance with JIS-A1412 (2016)).

### Example 1

In a 1,000 ml separable flask, 56 parts by mass of triphenylmethane type epoxy resin (trade name: EPPN-501H, weight average molecular weight: 1,000, softening point 55° C., solid, epoxy equivalent: 167, manufactured by Nippon Kayaku Co., Ltd.), 49 parts by mass of bisphenol A type epoxy resin (trade name: YD-128, weight average molecular weight: 400, softening point: 25° C. or lower, liquid, epoxy equivalent: 190, manufactured by NSCC Epoxy Manufacturing Co., Ltd.), 30 parts by mass of bisphenol A type phenoxy resin (trade name: YP-50, weight average molecular weight: 70,000, Tg: 84° C., manufactured by NSCC Epoxy Manufacturing Co., Ltd.), and 103 parts by mass of MEK were heated and stirred at a temperature of 110° C. for two hours. Thus, a resin varnish was obtained.

Then, 237 parts by mass of this resin varnish was transferred to a 800 ml planetary mixer, 196 parts by mass of alumina filler (trade name: AO-502, sphericity 0.99, average particle diameter (d50): 0.5 μm, manufactured by Admatechs) was added to the mixer, and 2.0 parts by mass of imidazole type curing agent (trade name: 2PHZ-PW, manufactured by Shikoku Chemicals Corporation) and 3.0 parts by mass of silane coupling agent (trade name: S-510, manufactured by JNC Corporation) were added to the mixer. The contents were stirred and mixed for one hour at room temperature. Thereafter, defoaming under vacuum was performed, thus obtaining a mixed varnish.

Then, the obtained mixed varnish was applied onto a release-treated PET film (release film) having a thickness of 38 μm, and heated and dried at 130° C. for 10 minutes to obtain a film-like adhesive in which an adhesive layer having a length of 300 mm, a width of 200 mm, and a thickness of 20 μm was stacked on the PET film.

### Example 2

A film-like adhesive of Example 2 was obtained in a similar manner to Example 1 except that the blending amount of the alumina filler was 305 parts by mass.

### Example 3

A film-like adhesive of Example 3 was obtained in a similar manner to Example 1 except that the blending amount of the alumina filler was 457 parts by mass.

### Example 4

A film-like adhesive of Example 4 was obtained in a similar manner to Example 2 except that the bisphenol A type phenoxy resin was replaced with 120 parts by mass of an acrylic polymer solution (trade name: S-2060, mass average molecular weight: 500,000, Tg: −23° C., solid content 25% (organic solvent: toluene), manufactured by Toagosei Co., Ltd.) (including 30 parts by mass of an acrylic polymer).

### Example 5

A film-like adhesive of Example 5 was obtained in a similar manner to Example 1 except that the alumina filler was replaced with 169 parts by mass of aluminum nitride filler (trade name: TFZ-A02P, sphericity 0.65, average particle diameter (d50): 1.1 μm; manufactured by Toyo Aluminum K.K.).

### Example 6

A film-like adhesive of Example 6 was obtained in a similar manner to Example 5 except that the blending amount of the aluminum nitride filler was changed to 263 parts by mass.

### Example 7

A film-like adhesive of Example 7 was obtained in a similar manner to Example 5 except that the blending amount of the aluminum nitride filler was changed to 394 parts by mass.

### Example 8

A film-like adhesive of Example 8 was obtained in a similar manner to Example 1 except that the alumina filler was replaced with 332 parts by mass of silver-coated silicone filler (trade name: SC0280-SF, sphericity 0.98, average particle diameter (d50): 5.8 μm; manufactured by Mitsubishi Materials Electronic Chemicals Co., Ltd.).

### Example 9

A film-like adhesive of Example 9 was obtained in a similar manner to Example 1 except that the alumina filler was replaced with 656 parts by mass of silver filler (trade name: AG-4-54F, sphericity 0.86, average particle diameter (d50): 2.0 μm; manufactured by DOWA ELECTRONICS MATERIALS CO., LTD.).

### Example 10

A film-like adhesive of Example 10 was obtained in a similar manner to Example 1 except that the alumina filler was replaced with 688 parts by mass of nickel filler (trade name: CN050, sphericity 0.92, average particle diameter (d50): 3.0 μm; manufactured by NIKKO RICA CORPORATION).

### Example 11

A film-like adhesive of Example 11 was obtained in a similar manner to Example 1 except that the blending amount of the alumina filler was 465 parts by mass and the blending amount of the imidazole-based curing agent was 4.0 parts by mass.

### Comparative Example 1

A film-like adhesive of Comparative Example 1 was obtained in a similar manner to Example 1 except that the alumina filler was replaced with 196 parts by mass of alumina filler (trade name: SA32, sphericity 0.57, average particle diameter (d50): 1.0 μm, manufactured by Nippon Light Metal Co., Ltd.).

### Comparative Example 2

A film-like adhesive of Comparative Example 2 was obtained in a similar manner to Comparative Example 1 except that the blending amount of the alumina filler was 457 parts by mass.

### Comparative Example 3

A film-like adhesive of Comparative Example 3 was obtained in a similar manner to Example 1 except that the alumina filler was replaced with 196 parts by mass of an alumina filler (trade name: AA33F, sphericity 0.59, average particle diameter (d50): 2.0 μm, manufactured by Nippon Light Metal Co., Ltd.).

### Comparative Example 4

A film-like adhesive of Comparative Example 4 was obtained in a similar manner to Comparative Example 3 except that the blending amount of the alumina filler was 457 parts by mass.

### Comparative Example 5

A film-like adhesive of Comparative Example 5 was obtained in a similar manner to Example 1 except that the alumina filler was replaced with 656 parts by mass of silver filler (trade name: AgC-204B, sphericity 0.57, average particle diameter (d50): 2.0 μm, manufactured by Fukuda Metal Foil & Powder Co., Ltd.).

### Comparative Example 6

A film-like adhesive of Comparative Example 6 was obtained in a similar manner to Example 1 except that the alumina filler was replaced with 688 parts by mass of nickel filler (trade name: Type255, sphericity 0.41, average particle diameter (d50): 2.5 μm; manufactured by NIKKO RICA CORPORATION).

### Comparative Example 7

A film-like adhesive of Comparative Example 7 was obtained in a similar manner to Example 1 except that the blending amount of the alumina filler was 214 parts by mass and the blending amount of the imidazole type curing agent was 15.0 parts by mass.

### Comparative Example 8

A film-like adhesive of Comparative Example 8 was obtained in a similar manner to Example 1 except that the blending amount of the alumina filler was 205 parts by mass and the blending amount of the imidazole type curing agent was 8.5 parts by mass.

### Comparative Example 9

A film-like adhesive of Comparative Example 9 was obtained in a similar manner to Example 1 except that the bisphenol A type phenoxy resin was replaced with 200 parts by mass of an acrylic polymer solution (trade name: TEISANRESIN SG-600TEA, mass average molecular weight: 1,200,000, Tg: −36° C., solid content: 15% (organic solvent: toluene/ethyl acetate mixed solvent), manufactured by Nagase ChemteX Corporation) (including 30 parts by mass of an acrylic polymer).

Compositions, characteristics, and evaluation results of the film-like adhesives with release films of Examples 1 to 11 and Comparative Examples 1 to 9 are shown in Tables below.

TABLE 1-1

| | | | Example | | | | | | | | | | |
|---|---|---|---|---|---|---|---|---|---|---|---|---|---|
| | | | 1 | 2 | 3 | 4 | 5 | 6 | 7 | 8 | 9 | 10 | 11 |
| Film-like | Epoxy | EPPN-501H | 56 | 56 | 56 | 56 | 56 | 56 | 56 | 56 | 56 | 56 | 56 |
| adhesive | resin (A) | (Triphenylmethane- | | | | | | | | | | | |
| [parts | | type epoxy resin) | | | | | | | | | | | |
| by mass] | | YD-128 | 49 | 49 | 49 | 49 | 49 | 49 | 49 | 49 | 49 | 49 | 49 |
| | | (Liquid Bis A-type | | | | | | | | | | | |
| | | epoxy resin) | | | | | | | | | | | |
| | Polymer | YP-50 (Bis A-type | 30 | 30 | 30 | | 30 | 30 | 30 | 30 | 30 | 30 | 30 |
| | component | phenoxy resin) | | | | 30 | | | | | | | |
| | (C) | S-2060 (Acrylic resin) | | | | | | | | | | | |
| | Inorganic | AO502 (sphericity 0.99, | 196 | 305 | 457 | 305 | | | | | | | 465 |
| | filler (D) | average particle diameter | | | | | | | | | | | |
| | | 0.5 μm, alumina filler) | | | | | | | | | | | |
| | | TFZ-A02P (sphericity 0.65, | | | | | 169 | 263 | 394 | | | | |
| | | average particle diameter | | | | | | | | | | | |
| | | 1.1 μm AIN filler) | | | | | | | | | | | |
| | | SC0280-SF (sphericity 0.98, | | | | | | | | 332 | | | |
| | | average particle diameter | | | | | | | | | | | |
| | | 5.8 μm, silver-coated | | | | | | | | | | | |
| | | silicone filler) | | | | | | | | | | | |
| | | AG-4-54F (sphericity 0.86, | | | | | | | | | 656 | | |
| | | average particle diameter | | | | | | | | | | | |
| | | 2.0 μm, silver filler) | | | | | | | | | | | |
| | | CN050 (sphericity 0.92, | | | | | | | | | | 688 | |
| | | average particle diameter | | | | | | | | | | | |
| | | 3.0 μm, Ni filler) | | | | | | | | | | | |
| | Surface | S-510 (Epoxysilane-type | 3 | 3 | 3 | 3 | 3 | 3 | 3 | 3 | 3 | 3 | 3 |
| | treatment agent | silane coupling agent) | | | | | | | | | | | |
| | Epoxy resin | 2PHZ-PW | 2 | 2 | 2 | 2 | 2 | 2 | 2 | 2 | 2 | 2 | 4 |
| | curing agent | (Imidazole-based | | | | | | | | | | | |
| | (B) | curing agent) | | | | | | | | | | | |

| | | | | | | | | | | | |
|---|---|---|---|---|---|---|---|---|---|---|---|
| Blended amount in terms of | 336 | 445 | 597 | 445 | 309 | 403 | 534 | 472 | 796 | 828 | 607 |
| total solid content [parts by mass] | | | | | | | | | | | |
| Inorganic filler amount [vol %] | 30 | 40 | 50 | 40 | 30 | 40 | 50 | 40 | 35 | 40 | 50 |

| | | | | | | | | | | | |
|---|---|---|---|---|---|---|---|---|---|---|---|
| Capillary rheometer viscosity [Pa · s] | 40 | 109 | 380 | 560 | 85 | 185 | 476 | 85 | 130 | 95 | 395 |
| Exothermic peak rise time in 120° C. | 21 | 24 | 27 | 20 | 20 | 22 | 23 | 19 | 23 | 24 | 15 |
| hold DSC measurement T1 [min] | | | | | | | | | | | |
| Exothermic peak end time in 120° C. | 63 | 68 | 72 | 64 | 60 | 64 | 67 | 58 | 63 | 67 | 40 |
| hold DSC measurement T2 [min] | | | | | | | | | | | |
| Exothermic peak detection time in 120° C. | 42 | 44 | 45 | 44 | 40 | 42 | 44 | 39 | 40 | 43 | 25 |
| hold DSC measurement T2-T1 [min] | | | | | | | | | | | |
| Evaluation of void after | AAA | AA | AA | AA | AAA | AA | A | AAA | A | AAA | AA |
| mounting and curing | | | | | | | | | | | |
| Thermal conductivity [W/m · K] | 1.0 | 1.5 | 1.8 | 1.5 | 1.8 | 2.4 | 3.2 | 6.2 | 25.0 | 1.2 | 1.9 |

TABLE 1-2

| | | | Comparative Example | | | | | | | | |
|---|---|---|---|---|---|---|---|---|---|---|---|
| | | | 1 | 2 | 3 | 4 | 5 | 6 | 7 | 8 | 9 |
| Film-like | Epoxy | EPPN-501H | 56 | 56 | 56 | 56 | 56 | 56 | 56 | 56 | 56 |
| adhesive | resin (A) | (Triphenylmethane-type | | | | | | | | | |
| [parts | | epoxy resin) | | | | | | | | | |
| by mass] | | YD-128 | 49 | 49 | 49 | 49 | 49 | 49 | 49 | 49 | 49 |
| | | (Liquid Bis A-type | | | | | | | | | |
| | | epoxy resin) | | | | | | | | | |
| | Polymer | YP-50 (Bis A-type | 30 | 30 | 30 | 30 | 30 | 30 | 30 | 30 | |
| | | phenoxy resin) | | | | | | | | | |
| | component (C) | SG-600TEA (Acrylic resin) | | | | | | | | | 30 |
| | Inorganic | AO502 (sphericity 0.99, | | | | | | | 214 | 205 | 196 |
| | filler (D) | average particle diameter | | | | | | | | | |
| | | 0.5 μm, alumina filler) | | | | | | | | | |
| | | SA32 (sphericity 0.57, | 196 | 457 | | | | | | | |
| | | average particle diameter | | | | | | | | | |
| | | 1.0 μm, alumina filler) | | | | | | | | | |
| | | A33F (sphericity 0.59, | | | 196 | 457 | | | | | |
| | | average particle diameter | | | | | | | | | |
| | | 2.0 μm, alumina filler) | | | | | | | | | |
| | | AgC-204B (sphericity 0.57, | | | | | 656 | | | | |
| | | average particle diameter | | | | | | | | | |
| | | 2.0 μm, silver filler) | | | | | | | | | |
| | | Type 255 (sphericity 0.41, | | | | | | 688 | | | |
| | | average particle diameter | | | | | | | | | |
| | | 2.5 μm, Ni filler) | | | | | | | | | |
| | Surface | S-510 | 3 | 3 | 3 | 3 | 3 | 3 | 3 | 3 | 3 |
| | treatment agent | (Epoxysilane-type | | | | | | | | | |
| | | silane coupling agent) | | | | | | | | | |
| | Epoxy resin | 2PHZ-PW | 2 | 2 | 2 | 2 | 2 | 2 | 15 | 8.5 | 2 |
| | curing agent (B) | (Imidazole-based | | | | | | | | | |
| | | curing agent) | | | | | | | | | |

| | | | | | | | | | |
|---|---|---|---|---|---|---|---|---|---|
| Blended amount in terms of total solid | 336 | 597 | 336 | 597 | 796 | 828 | 367 | 352 | 336 |
| content [parts by mass] | | | | | | | | | |
| Inorganic filler amount [vol %] | 30 | 50 | 30 | 50 | 35 | 40 | 30 | 30 | 30 |

| | | | | | | | | | |
|---|---|---|---|---|---|---|---|---|---|
| Capillary rheometer viscosity [Pa · s] | 1100 | 3459 | 1030 | 2840 | 1120 | 5430 | 39 | 30 | 1050 |
| Exothermic peak rise time in 120° C. | 25 | 26 | 18 | 19 | 20 | 23 | 10 | 10 | 21 |
| hold DSC measurement T1 [min] | | | | | | | | | |
| Exothermic peak end time in 120° C. | 70 | 71 | 65 | 67 | 62 | 68 | 23 | 23 | 66 |
| hold DSC measurement T2 [min] | | | | | | | | | |
| Exothermic peak detection time in 120° C. | 45 | 45 | 47 | 48 | 42 | 45 | 13 | 14 | 45 |
| hold DSC measurement T2-T1 [min] | | | | | | | | | |
| Evaluation of void after mounting and curing | B | C | B | C | B | C | B | B | B |
| Thermal conductivity [W/m · K] | 0.8 | 1.5 | 1.2 | 1.7 | 8.9 | 1.5 | 1.3 | 1.0 | 1.4 |

### <Notes in Tables>

A blank in a column of the inorganic filler (D) means that the corresponding component is not contained.

The “inorganic filler amount [vol %]” is a proportion (% by volume) of the inorganic filler (D) in the total content of the epoxy resin (A), the polymer component (C), the inorganic filler (D), and the epoxy resin curing agent (B).

In each of the film-like adhesives of Comparative Examples 1 to 6 and Comparative Example 9, the detection time of the exothermic peak in 120° C. hold DSC measurement satisfies the definition of the present invention, but the capillary rheometer viscosity is higher than the definition of the present invention. Conversely, in Comparative Examples 7 and 8, the capillary rheometer viscosity falls within the definition of the present invention, but the detection time of the exothermic peak in 120° C. hold DSC measurement is shorter than that defined in the present invention. When each of the film-like adhesives according to these Comparative Examples was used as a die attach film, discharge of voids was insufficient even when the pressure curing time in the pressure oven was 90 minutes after the die attach step.

On the other hand, when each of the film-like adhesives of Examples 1 to 11 satisfying the definition of the present invention is used as a die attach film, voids could be completely removed even when the pressure curing time in the pressure oven was 90 minutes or less after the die attach step. In addition, each of these film-like adhesives contained a large amount of filler and exhibited a sufficiently high thermal conductivity.

The present invention has been described together with embodiments thereof. It is our intention that the invention should not be limited by any of the details of the description unless otherwise specified, but rather be construed broadly within its spirit and scope as set out in the attached claims.

### REFERENCE SIGNS LIST

1 Semiconductor wafer
2 Film-like adhesive layer
3 Dicing tape
4 Semiconductor chip
5 Semiconductor chip with film-like adhesive layer
6 Wiring board
7 Bonding wire
8 Sealing resin
9 Semiconductor package

1. A thermally conductive film-like adhesive comprising:
an epoxy resin (A);
an epoxy resin curing agent (B);
a polymer component (C); and
an inorganic filler (D),
wherein a capillary rheometer viscosity at a temperature of 120° C. and a load of 20 Kg is 1 to 1000 Pa·s, and
wherein a detection time of an exothermic peak in differential scanning calorimetry that performs holding at 120° C. is 15 minutes or longer.

2. The thermally conductive film-like adhesive according to claim 1,
wherein a proportion of the inorganic filler (D) to a total content of the epoxy resin (A), the epoxy resin curing agent (B), the polymer component (C), and the inorganic filler (D) is 30 to 70% by volume,
wherein the inorganic filler (D) has a sphericity of 0.6 to 1.0, and
wherein a cured product having a thermal conductivity of 1.0 W/m·K or more is provided after thermal curing.

3. The thermally conductive film-like adhesive according to claim 1, having a thickness of 1 to 20 μm.

4. The thermally conductive film-like adhesive according to claim 1, wherein the epoxy resin curing agent (B) contains an imidazole compound.

5. The thermally conductive film-like adhesive according to claim 4, wherein a content of the epoxy resin curing agent (B) per 100 parts by mass of the epoxy resin (A) is 0.5 to 7 parts by mass.

6. A dicing die attach film obtained by stacking a dicing film and the thermally conductive film-like adhesive according to claim 1.

7. A method of producing a semiconductor package, comprising:
a first step of thermocompression-bonding the thermally conductive film-like adhesive according to claim 1 to a back surface of a semiconductor wafer in which at least one semiconductor circuit is formed on a surface, and providing a dicing film via a layer of the thermally conductive film-like adhesive;
a second step of integrally dicing the semiconductor wafer and the adhesive layer to obtain a semiconductor chip with an adhesive layer on the dicing film;
a third step of removing the dicing film from the adhesive layer and thermocompression-bonding the semiconductor chip with an adhesive layer and a wiring board via the adhesive layer; and
a fourth step of thermally curing the adhesive layer.

8. The method of producing a semiconductor package according to claim 7, wherein the first step is a step of thermocompression-bonding the dicing die attach film according to claim 6 to a back surface of the semiconductor wafer.

9. The method of producing a semiconductor package according to claim 7, wherein the thermally curing in the fourth step is performed in a pressure oven set at 100 to 150° C.

10. A semiconductor package obtained by the producing method according to claim 7.
